(19) United States
(12) Patent Application Publication
(10) Pub. No.: US 2025/0216764 A1
(43) Pub. Date: Jul. 3, 2025

(54) EUV LITHOGRAPHY MASK BLANKS, EUV MASKS AND METHODS

(71) Applicant: Taiwan Semiconductor Manufacturing Company, Ltd., Hsinchu (TW)

(72) Inventors: Pei-Cheng HSU, Hsinchu (TW); Sih-Wei CHANG, Hsinchu (TW); Hsuan-I WANG, Hsinchu (TW); Yu-Hsiang KAO, Hsinchu (TW); Ching-Fang YU, Hsinchu (TW); Hsin-Chang LEE, Hsinchu (TW)

(21) Appl. No.: 18/614,445

(22) Filed: Mar. 22, 2024

Related U.S. Application Data
(60) Provisional application No. 63/615,167, filed on Dec. 27, 2023.

(51) Int. Cl. G03F 1/24

(52) U.S. Cl. CPC G03F 1/24

(57) ABSTRACT

An EUV lithography mask including a substrate, a patterned absorber layer including an alloy of rhodium. In some embodiments, the alloy of rhodium includes a group 5, group 6, group 9, group 10, or group 11 transition metal having a specific EUV refractive index and a specific EUV extinction coefficient. The disclosed EUV lithography masks reduce undesirable mask 3D effects.

### PRIORITY CLAIM AND CROSS-REFERENCE

This application claims the benefit of U.S. Provisional Patent Application No. 63/615,167, filed Dec. 27, 2023, which is incorporated by reference herein in its entirety.

### BACKGROUND

The semiconductor industry has experienced exponential growth. Technological advances in materials and design have produced generations of integrated circuits (ICs), where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

Photolithography utilizing extreme ultraviolet radiation (EUV) useful for achieving increased functional density. EUV photolithography utilizes a mask to produce patterns of reflected EUV radiation which is used to expose photosensitive materials such as photoresists.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an extreme ultraviolet (EUV) mask blank, in accordance with some embodiments.

FIG. 2 is a flowchart of a method for fabricating the EUV mask blank of FIG. 1, in accordance with some embodiments.

FIGS. 3A-3D are cross-sectional views of an EUV mask blank at various stages of the fabrication process of FIG. 2, in accordance with some embodiments.

FIGS. 3E-3G are cross-sectional view of embodiments of an EUV mask blank with different embodiments of an absorber layer configured in accordance with the present disclosure.

FIG. 4 is a cross-sectional view of an EUV mask, in accordance with some embodiments.

FIG. 5 is a flowchart of a method for fabricating the EUV mask of FIG. 4, in accordance with some embodiments.

FIGS. 6A-6G are cross-sectional views of an EUV mask at various stages of the fabrication process of FIG. 5, in accordance with some embodiments.

FIG. 7 is a schematic diagram of a lithography system, in accordance with some embodiments of the present disclosure.

FIG. 8 is a flowchart of a method of using an EUV mask, in accordance with embodiments of the present disclosure.

FIG. 9 depicts a “red zone” for use in identifying combinations of first and second materials used to form an alloy for use in an absorber layer of EUV masks blanks and masks of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the manufacture of integrated circuits (ICs), patterns representing different layers of the ICs are fabricated using a series of reusable photomasks (also referred to herein as photolithography masks or masks). The photomasks are used to transfer the design of each layer of the ICs onto a semiconductor substrate during the semiconductor device fabrication process.

With the shrinkage in IC size, various types of this lithography techniques such as immersion lithography utilizing wavelengths on the order of 193 nm from an ArF laser or extreme ultraviolet (EUV) light with a wavelength of 13.5 nm is employed in, for example, a lithographic process to enable transfer of very small patterns (e.g., nanometer-scale patterns) from a mask to a semiconductor wafer.

An ongoing desire to have more densely packed integrated devices has resulted in changes to the photolithography process in order to form smaller individual feature sizes. The minimum feature size or “critical dimension” (CD) obtainable by a process is determined approximately by the formula CD=K₁*λ/NA, where k₁ is a process-specific coefficient, λ is the wavelength of applied light/energy, and NA is the numerical aperture of the optical lens as seen from the substrate or wafer.

For fabrication of dense features with a given value of k₁, the ability to project a usable image of a small feature onto a wafer is limited by the wavelength λ and the ability of the projection optics to capture enough diffraction orders from an illuminated mask. When either dense features or isolated features are made from a photomask or a reticle of a certain size and/or shape, the transitions between light and dark at the edges of the projected image may not be sufficiently sharply defined to correctly form target photoresist patterns. As a result, features 150 nm or below in size may need to utilize phase shifting masks (PSMs) or techniques to enhance the image quality at the wafer, e.g., sharpening edges of features to improve resist profiles.

Phase-shifting generally involves selectively changing phases of part of the energy passing through a photomask/reticle so that the phase-shifted energy is additive or subtractive with energy that is not phase-shifted at the surface of the material on the wafer that is to be exposed and patterned. By carefully controlling the shape, location, and phase shift angle of mask features, the resulting photoresist patterns can have more precisely defined edges. As the feature size reduces, an imbalance of transmission intensity between the 0° and 180° phase portions and a phase shift that varies from 180° can result in significant critical dimension (CD) variation and placement errors for the photoresist pattern.

Phase shifts may be obtained in a number of ways. For example, one process known as attenuated phase shifting (AttPSM) utilizes a mask that includes a layer of non-opaque material that causes light passing through the non-opaque material to change in phase compared to light passing through transparent parts of the mask. In addition, the non-opaque material can adjust the amount (intensity/magnitude) of light transmitted through the non-opaque material compared to the amount of light transmitted through transparent portions of the mask.

Another technique is known as alternating phase shift, where the transparent mask material (e.g., quartz or SiO₂ substrate) is sized (e.g., etched) to have regions of different depths or thicknesses. The depths are selected to cause a desired relative phase difference in light passing through the regions of different depths/thicknesses. The resulting mask is referred to as an “alternating phase shift mask” or “alternating phase shifting mask” (AltPSM). AttPSM and AltPSMs are referred to herein as “APSM.” The descriptions of absorber materials and absorber layer configurations provided herein refer to AltPSMs; however, embodiments described herein are applicable to AttPSMs as well. The portion of the AltPSM having the thicker depth is referred to as the 0° phase portion, while the portion of the AltPSM having the lesser depth is referred to as the 180° phase portion. The depth difference allows the light to travel half of the wavelength in the transparent material, generating a phase difference of 180° between 0° and 180° portions. In some implementations, a patterned phase shifting material or absorber layer is located above the portions of the transparent mask substrate that has not been etched to different depths. The patterned phase shifting material is a material that affects the phase of the light passing through the phase shifting material such that the phase of the light passing through the phase shifting material is shifted relative to the phase of the light that does not pass through the phase shifting material, e.g., passes only through the transparent mask substrate material without passing through the phase shifting material. The phase shifting material can also reduce the amount of light transmitted through the phase shifting material relative to the amount of incident light that passes through portions of the mask not covered by the phase shifting material.

AltPSMs and AttPSMs are not without their drawbacks. For example, when EUV radiation is incident on an AltPSM or an AttPSM at a certain angle, reflection from the mask is potentially subjected to a shadowing effect or a mask induced imaging aberrations at the wafer these types of effects are sometimes referred to as mask 3D effects (M3D). Mask 3D effects may result, among other things, in reducing the contrast of aerial images and also the quality of resulting photoresist profiles.

In EUV lithography, to avoid overlap of incident light and reflected light, the EUV mask is illuminated with obliquely incident light that is tilted at a 6-degree angle relative to the axis perpendicular to the mask plane. The oblique incident EUV light is reflected by a reflective multilayer or absorbed or partially absorbed by an absorber layer. On that occasion, if the absorber layer is thick enough, shadows are formed around the absorber lines that can make the absorber shapes to appear wider. The mask shadowing effects, also known as mask 3D (M3D) effects, can result in unwanted feature-size dependent focus and pattern placement shifts. The mask 3D effects become worse as the technology node advances, accordingly, the absorber thickness has to be reduced as much as possible to minimize the impact of mask 3D effects.

In embodiments of the present disclosure, APSM structures and methods of producing such APSM structures are described. APSM structures in accordance with embodiments described herein include a patterned absorber layer which includes one or more sublayers of absorber material, e.g., one layer of absorber material making up the absorber layer, two sublayers of absorber material making up the absorber layer, three sublayers of absorber material making up the absorber layer or more than three sublayers of absorber material making up the absorber layer. In other embodiments, the absorber layer is provided as a nano-lamination of multiple nanolayers of the absorber material in which the nanolayers include different alloy absorber materials. In some embodiments, the individual nanolayers are less than 2 nm thick and the nano-lamination is between 15-70 nm thick. In other embodiments, the nano-lamination is 20-50 nm thick. The absorber material of the layer or sublayers of absorber material can be provided in a polycrystalline microstructure (e.g., a grain size of 1-5 nanometers) or an amorphous microstructure. In some embodiments, the absorber material of the various layers or sublayers is an alloy of a first material and a second material, with the first material being rhodium (Rh) and the second material has a EUV refractive index (n) (i.e., a refractive index for EUV radiation centered on a 13.5 nanometer wavelength) greater than the EUV refractive index of rhodium and the second material has an EUV extinction coefficient (k) (i.e., an extinction coefficient for EUV radiation centered on a 13.5 nanometer wavelength) greater than the EUV extinction coefficient of rhodium. In some embodiments, the absorber material contains oxygen (O), nitrogen (N), or boron (B). In some embodiments, the absorber layer has a thickness of about 15-70 nanometers. In other embodiments, the patterned absorber layer has a thickness of about 20-50 nanometers. In some embodiments, the first material has an EUV refractive index (n) of about 0.875 and an EUV extinction coefficient (k) of about 0.031. As used herein, the term “about” means within 5% of the listed value. In some embodiments, the second material has an EUV refractive index that is greater than the EUV refractive index of the first material, e.g., rhodium, and an EUV extinction coefficient greater than the EUV extinction coefficient of the first material. APSM structures including an absorber layer formed in accordance with embodiments disclosed herein exhibit reduced thicknesses which result in the masks being less susceptible to undesirable mask 3D effects that can result in unwanted feature size dependent focus and pattern placement shifts. APSM structures including an absorber layer formed in accordance with embodiments described exhibit high aerial image contrast as evaluated using normalized image log slope (NILS). Use of APSM structures formed in accordance with the present disclosure results in mask enhancement factors (MEEF) that are desirably low.

The following description describes fabrication of a lithography mask that involves a mask blank fabrication process and a mask fabrication process. During the mask blank fabrication process, a mask blank is formed by depositing suitable reflective layers (e.g., multiple reflective layers), a capping layer, a buffer layer, an absorber layer(s) and hard mask layer or hard mask layers on a suitable substrate, e.g., a low thermal expansion material (LTEM). A conductive layer may be provided on a backside of the low thermal expansion material substrate. The mask is formed by patterning the mask blank during the mask fabrication process. The formed mask will have a positive or negative design of a layer of a semiconductor device to be manufactured using the formed mask.

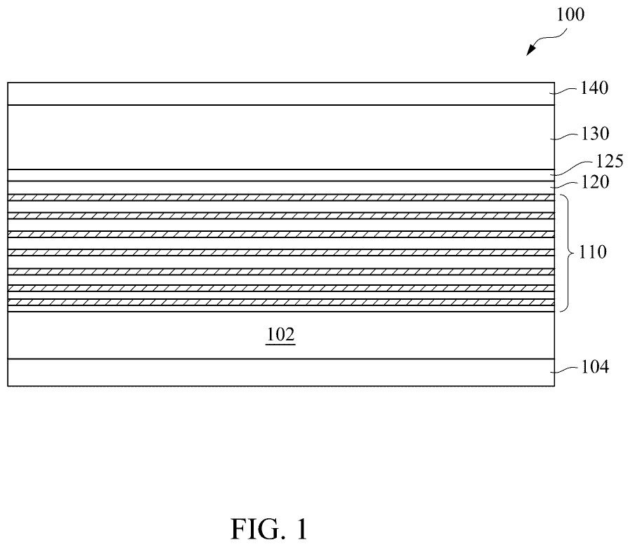

FIG. 1 is a cross-sectional view of an EUV mask blank 100, in accordance with a first embodiment of the present disclosure.

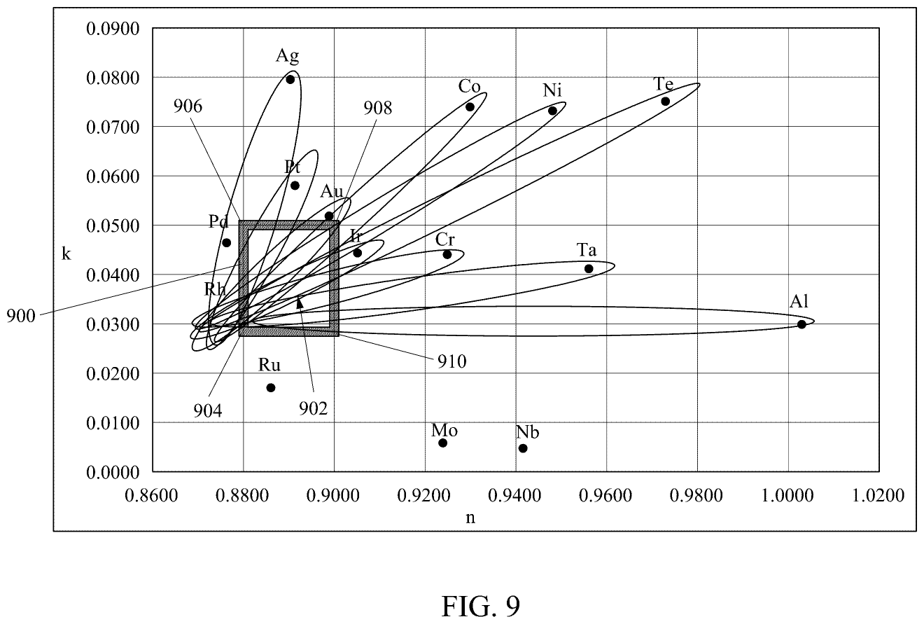

Referring to FIG. 1, the EUV mask blank 100 includes a substrate 102, a reflective multilayer stack 110 over a front surface of the substrate 102, a capping layer 120 over the reflective multilayer stack 110, a buffer layer 125 over the capping layer 120, an absorber layer 130 over the buffer layer 125, and a hard mask layer 140 over the absorber layer 130. The EUV mask blank 100 further includes a conductive layer 104 over a back surface of the substrate 102 opposite the front surface. The absorber layer 130 includes an alloy of a first material and a second material, the first material having an EUV refractive index (n) and an EUV extinction coefficient (k) and the second material having an EUV refractive index (n) and an EUV extinction coefficient (k). In a plot of EUV refractive index (n) vs EUV extinction coefficient (k) for the first material and the second material, a line between a first material coordinate defined by the EUV refractive index (n) and the EUV extinction coefficient (k) of the first material and a second material coordinate defined by the EUV refractive index (n) and the EUV extinction coefficient (k) of the second material passes through a polygon defined in the plot (e.g., FIG. 9) by four coordinates (n, k), the four coordinates being (0.880, 0.030), (0.880, 0.050), (0.900, 0.050) and (0.900, 0.030). Further details of the alloy of the first material and the second material and the deployment of the alloy in one layer or multiple layers are described below in more detail.

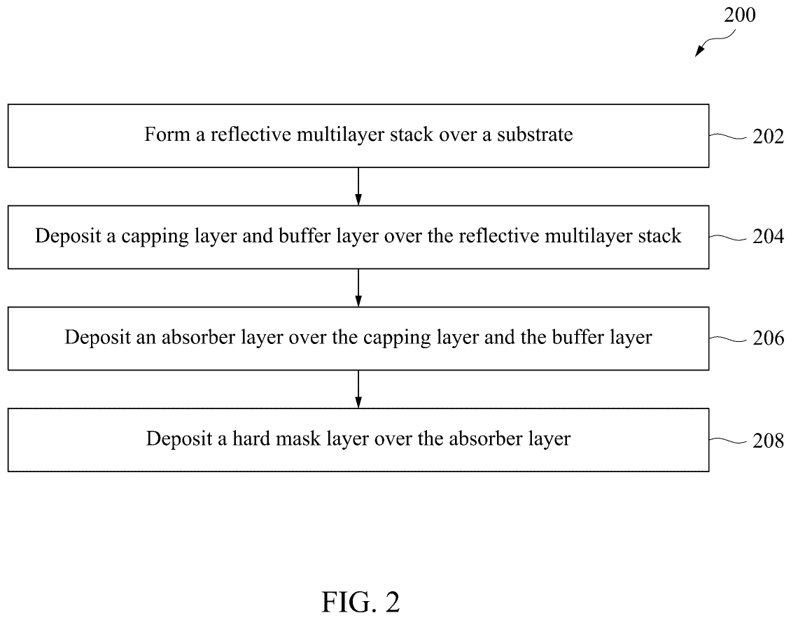

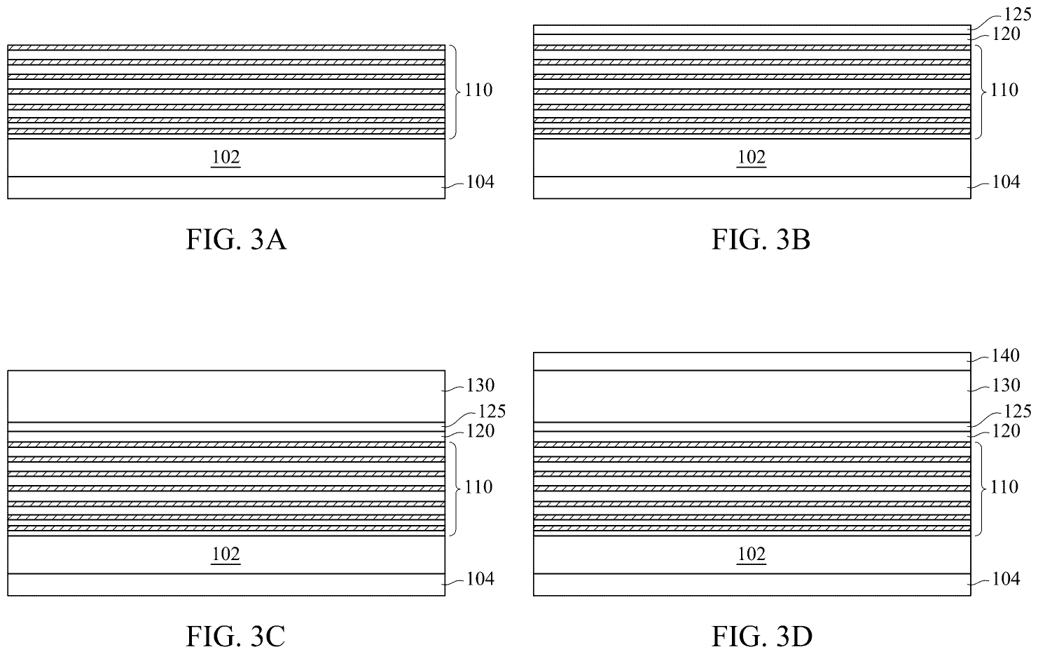

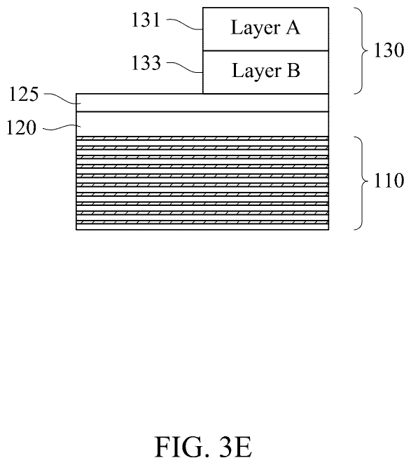

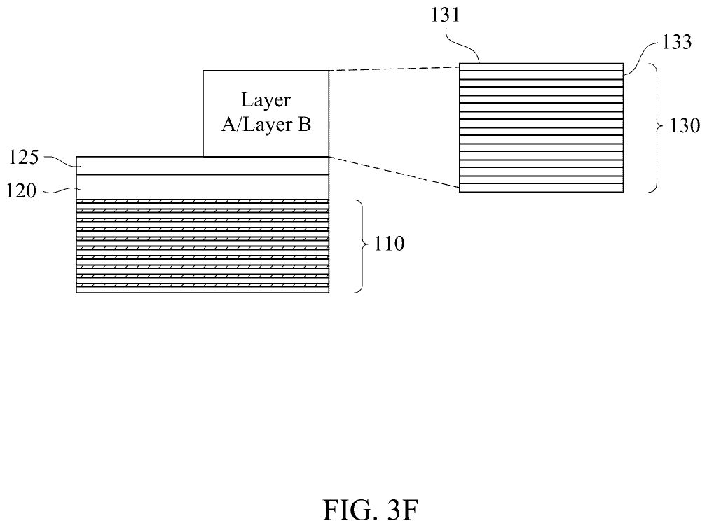

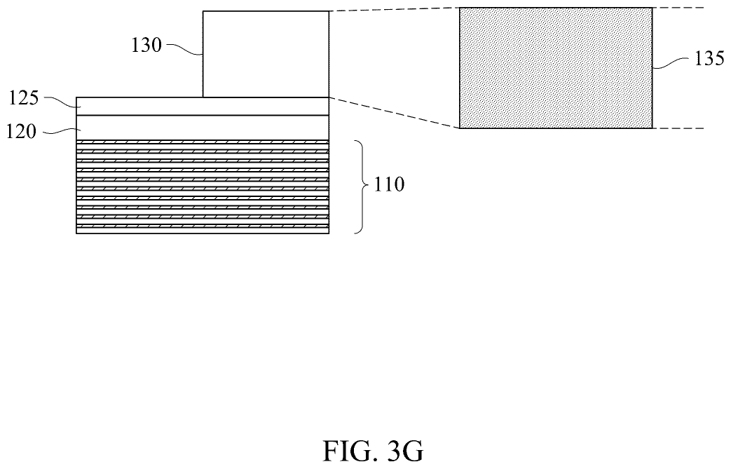

FIG. 2 is a flowchart of a method 200 for fabricating an EUV mask blank, for example, EUV mask blank 100 in FIG. 1, in accordance with some embodiments. FIG. 3A through FIG. 3D are cross-sectional views of the EUV mask blank 100 at various stages of the fabrication process, in accordance with some embodiments. The method 200 is discussed in detail below, with reference to the EUV mask blank 100. In some embodiments, additional operations are performed before, during, and/or after the method 200, or some of the operations described are replaced and/or eliminated. In some embodiments, some of the features described below are replaced or eliminated. One of ordinary skill in the art would understand that although some embodiments are discussed with operations performed in a particular order, these operations may be performed in another logical order.

Referring to FIGS. 2 and 3A, the method 200 includes operation 202, in which a reflective multilayer stack 110 is formed over a substrate 102, in accordance with some embodiments. FIG. 3A is a cross-sectional view of an initial structure of an EUV mask blank 100 after forming the reflective multilayer stack 110 over the substrate 102, in accordance with some embodiments.

Referring to FIG. 3A, the initial structure of the EUV mask blank 100 includes a substrate 102 made of glass, silicon, quartz, or other low thermal expansion materials. The low thermal expansion material helps to minimize image distortion due to mask heating during use of an EUV mask formed from the EUV mask blank 100. In some embodiments, the substrate 102 includes fused silica, fused quartz, calcium fluoride, silicon carbide, black diamond, or titanium oxide doped silicon oxide (SiO₂/TiO₂). In some embodiments, the substrate 102 has a thickness ranging from about 1 mm to about 7 mm. If the thickness of the substrate 102 is too small, a risk of breakage or warping of the EUV mask blank 100 increases, in some instances. On the other hand, if the thickness of the substrate is too great, a weight of the EUV mask blank 100 is needlessly increased, in some instances. Such excess weight can lead to warping and distortion of masks from mask blank 100.

In some embodiments, a conductive layer 104 is disposed on a back surface of the substrate 102. In some embodiments, the conductive layer 104 is in direct contact with the back surface of the substrate 102. The conductive layer 104 is adapted to provide for electrostatically coupling of the EUV mask blank 100 to an electrostatic mask chuck (not shown) during fabrication the EUV mask blank 100. In some embodiments, the conductive layer 104 includes chromium nitride (CrN) or tantalum boride (TaB). In some embodiments, the conductive layer 104 is formed by a deposition process such as, for example, chemical vapor deposition (CVD), plasma-enhanced chemical vapor deposition (PECVD), or physical vapor deposition (PVD). The thickness of the conductive layer 104 is controlled such that the conductive layer 104 is optically transparent. In other embodiments a conductive layer 104 is not disposed on a back surface of the substrate 102.

The reflective multilayer stack 110 is disposed over a front surface of the substrate 102 opposite the back surface. In some embodiments, the reflective multilayer stack 110 is in direct contact with the front surface of the substrate 102. The reflective multilayer stack 110 provides a high reflectivity to EUV light incident on the reflective multilayer stack 110. In some embodiments, the reflective multilayer stack 110 is configured to achieve about 60% to about 75% reflectivity at the peak EUV illumination wavelength, e.g., the EUV illumination at 13.5 nm. Specifically, when the EUV light is applied at an incident angle of 4-7° to the surface of the reflective multilayer stack 110 a desired reflectivity of light is achieved. For example, when the incident angle is 6°, the maximum reflectivity of light in the vicinity of a wavelength of 13.5 nm is about 60%, about 62%, about 65%, about 68%, about 70%, about 72%, or about 75%.

In some embodiments, the reflective multilayer stack 110 includes alternatively stacked layers of a high refractive index material and a low refractive index material. A material having a high refractive index tends to scatter EUV light on the one hand, and a material having a low refractive index tends to transmit EUV light on the other hand. Pairing these two type materials together provides a resonant reflectivity. In some embodiments, the reflective multilayer stack 110 includes alternatively stacked molybdenum (Mo) layers and silicon (Si) layers. In some embodiments, the reflective multilayer stack 110 includes alternatively stacked Mo and Si layers with a Si layer being the topmost layer. In some embodiments, a Mo layer is in direct contact with the front surface of the substrate 102. In other some embodiments, a Si layer is in direct contact with the front surface of the substrate 102. Alternatively, the reflective multilayer stack 110 includes alternatively stacked layers of Mo and beryllium (Be).

The thickness of each layer in the reflective multilayer stack 110 depends on the EUV wavelength and the incident angle of the EUV light. The thickness of alternating layers in the reflective multilayer stack 110 is tuned to maximize the constructive interference of the EUV light reflected at each interface and to minimize the overall absorption of the EUV light. In some embodiments, the reflective multilayer stack 110 includes from 20 to 60 pairs of alternating Mo layers and Si layers. Each Mo and Si layer pair may have a thickness ranging from about 2 nm to about 7 nm, with a total thickness ranging from about 100 nm to about 300 nm.

In some embodiments, each layer in the reflective multilayer stack 110 is deposited over the substrate 102 and underlying layer using ion beam deposition (IBD) or DC magnetron sputtering. The deposition method used helps to ensure that the thickness uniformity of the reflective multilayer stack 110 is better than about 0.85 across the substrate 102. For example, to form a Mo/Si reflective multilayer stack 110, a Mo layer is deposited using a Mo target as the sputtering target and an argon (Ar) gas (having a gas pressure of from 1.3×10⁻² Pa to 2.7×10⁻Pa) as the sputtering gas with an ion acceleration voltage of from 300 V to 1,500 V at a deposition rate of from 0.03 to 0.30 nm/sec and then a Si layer is deposited using a Si target as the sputtering target and an Ar gas (having a gas pressure of 1.3×10⁻² Pa to 2.7×10⁻2 Pa) as the sputtering gas, with an ion acceleration voltage of from 300 V to 1,500 V at a deposition rate of from 0.03 to 0.30 nm/sec. By stacking Si layers and Mo layers in 20 to 60 cycles, each of the cycles comprising the above steps, the Mo/Si reflective multilayer stack is deposited.

Referring to FIGS. 2 and 3B, the method 200 proceeds to operation 204, in which a capping layer 120 is deposited over the reflective multilayer stack 110, in accordance with some embodiments. FIG. 3B is a cross-sectional view of the structure of FIG. 3A after depositing the capping layer 120 over the reflective multilayer stack 110, in accordance with some embodiments.

Referring to FIG. 3B, the capping layer 120 is disposed over the topmost surface of the reflective multilayer stack 110. The capping layer 120 helps to protect the reflective multilayer stack 110 from oxidation and any chemical etchants to which the reflective multilayer stack 110 may be exposed during subsequent mask blank and mask fabrication processes. In some embodiments, capping layer 120 is 2 to 5 nanometers thick. Embodiments in accordance with the present disclosure are not limited to capping layers that are 2 to 5 nanometers thick. For example, in other embodiments, capping layer 120 can have a thickness that is less than 2 nanometers or a thickness that is greater than 5 nanometers.

In some embodiments, the capping layer 120 includes a material that resists oxidation and corrosion, and has a low chemical reactivity with common atmospheric gas species such as oxygen, nitrogen, and water vapor. In some embodiments, the capping layer 120 includes a transition metal such as, for example, ruthenium (Ru), iridium (Ir), rhodium (Rh), platinum (Pt), palladium (Pd), osmium (Os), rhenium (Re), vanadium (V), tantalum (Ta), hafnium (Hf), tungsten (W), molybdenum (Mo), zirconium (Zr), manganese (Mn), technetium (Tc), or alloys thereof. In some embodiments, the capping layer 120 includes one or more of oxygen (O), niobium (Nb), nitrogen (N) in combination with one or more of the foregoing transition metals.

In some embodiments, the capping layer 120 is formed using a deposition process such as, for example, IBD, CVD, PECVD, PVD, or atomic layer deposition (ALD). The deposition of the capping layer 120 is often carried out at a relatively low temperature, for example, less than 150° C., to prevent inter-diffusion of the reflective multilayer stack 110. In instances where a Ru layer is to be formed as the capping layer 120 using IBD, the deposition may be carried out in an Ar atmosphere by using a Ru target as the sputtering target.

Referring to FIGS. 2 and 3C, the method 200 proceeds to operation 206, in which a buffer layer 125 is deposited or formed over the capping layer 120 and then an absorber layer 130 is deposited or formed over the buffer layer 125, in accordance with some embodiments. FIG. 3C is a cross-sectional view of the structure of FIG. 3B after depositing the buffer layer 125 over the capping layer 120 and then depositing the absorber layer 130 over the buffer layer 125, in accordance with some embodiments.

In some embodiments, the buffer layer 125 is formed on the capping layer 120 as an etch stop layer for patterning the absorber layer 130. The buffer layer 125 can also serve as a sacrificial layer during a subsequent focused ion beam defect repair process for the absorber layer 130. In some embodiments, the buffer layer is formed of a material containing tantalum (Ta), silicon (Si) or molybdenum (Mo) with or without other elements such as boron, oxygen, nitrogen, or carbon. The buffer layer may be formed from TaBO, TaBN, TaN, Ta₂O₅, TaO₂, TaO, Ta₂O, MoSi, MoSiN, MoSiO, SiN, SiON, SiO₂, SiCON, SiC, SiCN, or other suitable materials. In some embodiments, buffer layer 125 has a thickness between 2 and 20 nanometers. Embodiments in accordance with the present disclosure are not limited to a buffer layer 125 having a thickness between 2 and 20 nm. In other embodiments, buffer layer 125 has a thickness that is less than 2 nm or greater than 20 nm.

The absorber layer 130 is usable for absorbing radiation projected onto an EUV mask formed from the EUV mask blank. The absorber layer 130 includes an absorber material that includes an alloy of a first material and a second material, the first material having an EUV refractive index (n) and an EUV extinction coefficient (k) and the second material having an EUV refractive index (n) and an EUV extinction coefficient (k). In some embodiments, the first material and the second material are related in the following manner. In a plot of EUV refractive index (n) vs EUV extinction coefficient (k) for the first material and the second material (e.g., FIG. 9), a line between a first material coordinate defined by the EUV refractive index (n) and the EUV extinction coefficient (k) of the first material and a second material coordinate defined by the EUV refractive index (n) and the EUV extinction coefficient (k) of the second material passes through a red zone defined in the plot by four coordinates (n, k), the four coordinates being (0.880, 0.030), (0.880, 0.050), (0.900, 0.050) and (0.900, 0.030). FIG. 9 described below in more detail includes an example of a polygon 900 representing this red zone. In some embodiments, the second material is one or more of tantalum (Ta), chromium (Cr), cobalt (Co), iridium (Ir), nickel (Ni), palladium (Pd), platinum (Pt), silver (Ag), gold (Au), aluminum (Al) or tellurium (Te). In some embodiments, the alloy includes one or more of oxygen (O), nitrogen (N) or boron (B). In some embodiments, the absorber layer 130 includes two or more of the foregoing alloys.

In some embodiments, the absorber material of the absorber layer 130 includes an alloy of a first material and a second material, wherein the first material is a group 9 transition metal, such as rhodium (Rh), and rhodium has an EUV refractive index (n) and an EUV extinction coefficient (k). The second material is a group 5, group 6, group 9, group 10, or group 11 transition metal having an EUV refractive index (n) greater than the EUV refractive index (n) of rhodium and an EUV extinction coefficient (k) greater than the EUV extinction coefficient (k) of rhodium. In embodiments where the first material is rhodium, the alloy of the absorber material contains 10 to 75 atomic % rhodium. In some embodiments where the first material is rhodium, the second material is one or more of tantalum (Ta), chromium (Cr), cobalt (Co), iridium (Ir), nickel (Ni), palladium (Pd), platinum (Pt), silver (Ag), gold (Au), aluminum (Al) or tellurium (Te). In some embodiments, the rhodium-containing alloy includes one or more of oxygen (O), nitrogen (N) or boron (B). In some embodiments, the absorber layer 130 includes two or more of the foregoing alloys.

In some embodiments, an EUV mask including an absorber layer 130 including an absorber material in accordance with embodiments described herein, shifts a phase of EUV radiation (i.e., a phase shift) incident on a patterned absorber layer 130 by 1.17π to 1.20π compared to the phase of the EUV radiation reflected from a surface of the capping layer 120. Embodiments in accordance with the present disclosure are not limited to absorber materials that are able to shift a phase of EUV radiation within the range described above. In other embodiments, the absorber material is able to shift the phase of the EUV radiation by less than 1.17π or greater than 1.20π. When the absorber material is able to use shift a phase of the EUV radiation by 1.17π to 1.20π, the aerial image will be sharp and have minimal blur. In addition, a level of the mask 3D effect, near field effect and reflection phase shift will be more desirable than if the phase shift is less than 1.17π or greater than 1.20π. In accordance with some embodiments, reflectance of EUV radiation incident on portions of the patterned absorber layer 130 of the EUV mask is 1-15% of reflectance of EUV radiation incident on portions of the EUV mask that are not covered by the patterned absorber layer 130. As used herein, reflectance refers to the amount of electromagnetic radiation reflected from a surface or optical element. Reflectance can be represented as a ratio of reflected electromagnetic energy and incident electromagnetic energy. As a result, the focus shifts and pattern placement errors resulting from mask 3D effects can be reduced, while the normalized image log-slope (NILS) can be increased.

As noted above, in some embodiments, the first material of the alloy is rhodium (Rh). Rhodium has an EUV refractive index (n) and an EUV extinction coefficient (k). The second material of the alloy of an absorber material in accordance with the present disclosure has an EUV refractive index (n) and an EUV extinction coefficient (k). In accordance with the present disclosure, in a plot of EUV refractive index (n) vs EUV extinction coefficient (k) for the first material, e.g., rhodium, and the second material, a line between a first material coordinate defined by the EUV refractive index (n) and the EUV extinction coefficient (k) of the first material and a second material coordinate defined by the EUV refractive index (n) and the EUV extinction coefficient (k) of the second material passes through a polygon defined in the plot by four coordinates (n, k), the four coordinates being (0.880, 0.030), (0.880, 0.050), (0.900, 0.050) and (0.900, 0.030).

In some embodiments, the second material is a group 5, group 6, group 9, group 10, or group 11 transition metal having an EUV refractive index (n) greater than the EUV refractive index (n) of rhodium and an EUV extinction coefficient (k) greater than the EUV extinction coefficient (k) of rhodium. Examples of such types of transition metals include tantalum (Ta), chromium (Cr), cobalt (Co), iridium (Ir), nickel (Ni), palladium (Pd), platinum (Pt), silver (Ag) and gold (Au). In some embodiments, the second material is a period 4, period 5, or period 6 transition metal. In some embodiments, the second material is aluminum (Al) or tellurium (Te). In some embodiments, the alloy of the first material and the second material includes one or more of oxygen (O), nitrogen (N) or boron (B). In some embodiments, the absorber layer 130 includes two or more of the foregoing alloys.

The absorber layer 130 can be deployed in a number of different ways. For example, referring to FIG. 3E, the absorber layer 130 can be deployed as a Layer A 131 over a Layer B 133 with Layer A having a different composition than Layer B. In some embodiments, Layer A 131 includes an alloy of a first material and a second material described above and Layer B 133 includes a different alloy of a first material and a second material described above. For example, in some embodiments, Layer A 131 includes a rhodium containing alloy that includes oxygen, oxygen and nitrogen or oxygen and boron and a second material. For example, Layer A 131 may include an alloy selected from RhPdO, RhAgO, RhPtO, RhAuO, RhCoO, RhNiO, RhIrO, RhTeO, RhCrO, RhTaO, RhAlO, RhPdON, RhAgON, RhPtON, RhAuON, RhCoON, RhNiON, RhIrON, RhTeON, RhCrON, RhTaON, RhAlON, RhPdOB, RhAgOB, RhPtOB, RhAuOB, RhCoOB, RhNiOB, RhIrOB, RhTeOB, RhCrOB, RhTaOB and RhAlOB. In some embodiments, Layer A, 131 is 10-40 nanometers thick, has a rhodium content of 20-75 atomic % and an oxygen/nitrogen/boron content of 2-20 atomic %. Embodiments in accordance with the present disclosure are not limited to Layer A being 10 to 40 nm thick. In some embodiments, Layer A can be less than 10 nm thick or greater than 40 nm thick. If the thickness of Layer A, 131 of the absorber layer 130 is too small, the absorber layer 130 may not be able to absorb a sufficient amount of the EUV light to generate a desired phase shift to produce a desired image contrast between portions of a mask covered by the absorber layer 130 and portions of a mask not covered by the absorber layer 130. On the other hand, if the thickness of Layer A, 131 of absorber layer 130 is too great, the precision of a pattern to be formed in the absorber layer 130 tends to be low. Embodiments in accordance with the present disclosure are not limited to Layer A having a rhodium content of 20-75 atomic %. In some embodiments, the rhodium content of Layer A is less than 20 atomic % or greater than 75 atomic %. If the rhodium content of Layer A is too low or too high, the absorber layer 130 may not be able to absorb a sufficient amount of the EUV light incident on the absorber layer 130 to generate a desired phase shift to produce a desired image contrast between portions of a mask covered by the absorber layer 130 and portions of a mask not covered by the absorber layer 130 or the precision of a pattern to be formed in the absorber layer 130 may be lower than desired. Embodiments in accordance with the present disclosure are not limited to Layer A having an oxygen/nitrogen/boron content of 2-20 atomic %. For example, in some embodiments, Layer A can have an oxygen/nitrogen/boron content that is less than 2 atomic % or greater than 20 atomic %. If the oxygen/nitrogen/boron content of Layer A is too low or too high, the absorber layer 130 may not be able to absorb a sufficient amount of the EUV light to generate a desired phase shift to produce a desired image contrast between portions of a mask covered by the absorber layer 130 and portions of a mask not covered by the absorber layer 130 or the precision of a pattern to be formed in the absorber layer 130 may be lower than desired.

In some embodiments of FIG. 3E, Layer B 133 includes a rhodium alloy that does not include oxygen, but may include nitrogen and/or boron. In addition, Layer B 133 includes a second material as described above. For example, Layer B 133 may include an alloy selected from RhPd, RhAg, RhPt, RhAu, RhCo, RhNi, RhIr, RhTe, RhCr, RhTa, RhAl, RhPdN, RhAgN, RhPtN, RhAuN, RhCoN, RhNiN, RhIrN, RhTeN, RhCrN, RhTaN, RhAlN, RhPdB, RhAgB, RhPtB, RhAuB, RhCoB, RhNiB, RhIrB, RhTeB, RhCrB, RhTaB and RhAlB. In some embodiments, Layer B 133 is 5-30 nanometers thick, has a rhodium content of 20-75 atomic % and a nitrogen/boron content of 2-20 atomic %. Embodiments in accordance with the present disclosure are not limited to Layer B being 5 to 30 nm thick. In some embodiments, Layer B can be less than 5 nm thick or greater than 30 nm thick. If the thickness of Layer B, 133 of the absorber layer 130 is too small, the absorber layer 130 may not be able to absorb a sufficient amount of the EUV light to generate the desired contrast between portions of a mask covered by the absorber layer 130 and portions of a mask not covered by the absorber layer 130. On the other hand, if the thickness of Layer B, 133 of absorber layer 130 is too great, the precision of a pattern to be formed in the absorber layer 130 may be lower than desired. Embodiments in accordance with the present disclosure are not limited to Layer B having a rhodium content of 20-75 atomic %. In some embodiments, the rhodium content of Layer B is less than 20 atomic % or greater than 75 atomic %. If the rhodium content of Layer B is too low or too high, the absorber layer 130 may not be able to absorb a sufficient amount of the EUV light to generate the desired contrast between portions of a mask covered by the absorber layer 130 and portions of a mask not covered by the absorber layer 130 or the precision of a pattern to be formed in the absorber layer 130 may be lower than desired. Embodiments in accordance with the present disclosure are not limited to Layer B having a nitrogen/boron content of 2-20 atomic %. For example, in some embodiments, Layer B can have a nitrogen/boron content that is less than 2 atomic % or greater than 20 atomic %. If the nitrogen/boron content of Layer B is too low or too high, the absorber layer 130 may not be able to absorb a sufficient amount of the EUV light to generate the desired contrast between portions of a mask covered by the absorber layer 130 and portions of a mask not covered by the absorber layer 130 or the precision of a pattern to be formed in the absorber layer 130 may be lower than desired.

In accordance with the embodiments of FIG. 3E Layer B 133 can be above or below Layer A 131. In some embodiments in accordance with FIG. 3E, the buffer layer 125 is selected from TaBN, TaN, MoSi, MoSiN, SiN, SiC, SiCN and has a thickness of 2 to 20 nanometers. In the same embodiments in accordance with FIG. 3E, the capping layer 120 is selected from Ru, RuO, RuNb, RuNbO, RuZr, RuZrN, RuRh, RuON, RuNbN, RuRhN, RuVO, RuV, RuVN and has a thickness of 2 to 5 nanometers. In other embodiments of FIG. 3E, buffer layer 125 is selected from CrN and Cr₂N and has a thickness of 2-20 nanometers. In the same embodiments of FIG. 3E, the capping layer 120 is selected from Ru, RuO, RuNb, RuNbO, RuZr, RuZrN, RuRh, RuON, RuNbN, RuRhN, RuVO, RuV, RuVN and has a thickness of 2 to 5 nanometers.

In some embodiments, the absorber layer 130 including Layer A and Layer B has a total thickness between 10-75 nanometers. In other embodiments Layer A and Layer B have a combined thickness of between 20-50 nanometers. In some embodiments, the thickness of Layer B is between 12 to 50% of the thickness of Layer A. When Layer A and Layer B have thicknesses within the foregoing ranges, combination of Layer A and Layer B provides an absorber layer 130 which has an index of refraction and a coefficient of extinction that falls within the red zone 902 of FIG. 9 described below. When absorber layer has an index of refraction and an extinction coefficient that falls within the red zone 902, absorber layer 130 provides a desired level of phase shifting and a desired level of reflectivity. When absorber layer 130, Layer A and Layer B have thicknesses outside the ranges described above, an absorber layer 130 including a combination of the materials of Layer A and Layer B may have an index of refraction and an extinction coefficient that does not fall with red zone 902 and the absorber layer may not provide a desired level of phase shifting or a desired level of reflectivity.

For the embodiments of FIG. 3E, the descriptions of capping layer 120 and buffer layer 125 provided above are equally applicable to the capping layer 120 and buffer layers used in embodiments of FIG. 3E.

In other embodiments illustrated in FIG. 3F, absorber layer 130 includes a plurality of alternating layers of a first alloy 131 of a first material described above and a second material described above and layers of a second alloy 133, different in composition from the first alloy 131, of a first material described above and a second material described above. In the embodiment illustrated in FIG. 3F, eight layers of the first alloy 131 and eight layers of the second alloy 133 are illustrated; however, embodiments in accordance with the present disclosure are not limited to eight layers of the first material 131 and eight layers of the second material 133. In other embodiments, more than eight layers, or fewer than eight layers of the first material or the second material can be provided. In the embodiment illustrated in FIG. 3F, the uppermost layer is a layer of the first alloy 131; however, in other embodiments, the uppermost layer can be a layer of the second alloy 133. In the embodiment illustrated in FIG. 3F, the lowermost layer is of the second alloy 133; however, in other embodiments, the lowermost layer can be a layer of the first alloy 131. The thickness of the individual layers of the first alloy 131 and the second alloy 133 can vary. For example, the thickness of each layer of the first alloy 131 and the second alloy 133 can be between 0.5 nm to 1.5 nm. In other embodiments, the thickness of each layer of the first alloy and the second alloy is less than 0.5 nm or greater than 1.5 nm. In some embodiments, the thickness of the layer of first alloy is unequal to the thickness of adjacent layers of the second alloy, or vice versa. In some embodiments, the absorber layer 130 including the multiple layers of the first alloy and the second alloy has a total thickness between 15-75 nanometers. In other embodiments the stack of layers of the first alloy 131 and second alloy 133 have a combined thickness of between 20-50 nanometers. In some embodiments, the combined thickness of the multiple layers of the second alloy is between 1-75% of the combined thickness of the multiple layers of the first alloy. When absorber layer 130, and the layers of the first alloy 131 and the layers of the second alloy 133 have thicknesses within the foregoing ranges, the refractive index and extinction coefficient of the combination of the first alloy and the second alloy forming the absorber layer 130 falls within the red zone 902 in FIG. 9 described below and the absorber layer 130 provides a desired level of phase shifting and a desired level of reflectivity. When absorber layer 130, and the layers of the first material 131 and the layers of the second material 133 have thicknesses that fall outside the foregoing ranges, the index of refraction and extinction coefficient of the combination of the first alloy and the second alloy may not fall within red zone 902 and the absorber layer 130 may not provide a desired level of phase shifting or a desired level of reflectivity. Embodiments in accordance with the present disclosure are not limited to the foregoing combined thicknesses of the layers of the first alloy and the layers of the second alloy, for example, the combined thickness of the layers of the first alloy can fall outside the foregoing range and the combined thickness of the layers of the second material can fall outside the foregoing range.

For the embodiments of FIG. 3F, the descriptions of capping layer 120 and buffer layer 125 provided above are equally applicable to the capping layer 120 and buffer layers used in embodiments of FIG. 3F.

In another embodiment, the absorber layer 130 is formed as a single layer of an alloy 135 of the first material described above and the second material described above. An alloy 135 is a substance composed of two or more metals or of a metal and a non-metal intimately united usually by being fused together and dissolving each other when molten. FIG. 3G illustrates an example of such type of an embodiment of the present disclosure. In some embodiments of FIG. 3G, the absorber layer 130 includes an alloy 135 of the first material and the second material and has a total thickness between 15-75 nanometers. In other embodiments absorber layer 130 has a combined thickness of between 20-50 nanometers. Embodiments in accordance with the present disclosure are not limited to the foregoing thicknesses, for example, absorber layer of FIG. 3G can have a thickness that falls outside the foregoing range. In some embodiments, the atomic % of the first material in the alloy is between 20-75%. Embodiments in accordance with the present disclosure are not limited to alloys having the foregoing atomic % of the first material. For example, embodiments in accordance with the present disclosure include alloys that contain less than 20 atomic % of the first material or more than 75 atomic % of the first material. When atomic % of the first material of the absorber layer 130 falls within the foregoing range, the index of refraction and extinction coefficient of the combination of the first material and the second material falls within the red zone 902 of FIG. 9 described below and the absorber layer provides a desired level of phase shifting and a desired level of reflectivity. When the atomic % of the first material of the alloy forming the absorber layer 130 falls outside the foregoing range, the index of refraction and coefficient of extinction of the absorber layer 130 may not fall within red zone 902 and may not provide a desired level of phase shifting and/or level of reflectivity. Embodiments of FIG. 3G in accordance with the present disclosure are not limited to an atomic % of the first material of the absorber layer 130 within the foregoing range. For example, the atomic % of the first material in the absorber layer in accordance with FIG. 3G can fall above or below the foregoing range.

For the embodiments of FIG. 3G, the descriptions of capping layer 120 and buffer layer 125 provided above are equally applicable to the capping layer 120 and buffer layers used in embodiments of FIG. 3G.

In accordance with embodiments in accordance with FIG. 3G, exemplary alloys 135 for absorber layer 130 are as follows. In some embodiments, alloys 135 for use in absorber layer 130 include RhPd, RhAg, RhPt, RhAu, RhCo, RhNi, RhIr, RhTe, RhCr, RhTa, RhAl, RhPdN, RhAgN, RhPtN, RhAuN, RhCON, RhNiN, RhIrN, RhTeN, RhCrN, RhTaN, RhAlN, RhPdB, RhAgB, RhPtB, RhAuB, RhCoB, RhNiB, RhIrB, RhTeB, RhCrB, RhTaB and RhAlB. In other embodiments, the alloy 135 of the absorber layer 130 includes oxygen, nitrogen and/or boron. For example, alloys 135 for use in absorber layer 130 include RhPdO, RhAgO, RhPtO, RhAuO, RhCoO, RhNiO, RhIrO, RhTeO, RhCrO, RhTaO, RhAlO, RhPdON, RhAgON, RhPtON, RhAuON, RhCoON, RhNiON, RhIrON, RhTeON, RhCrON, RhTaON, RhAlON, RhPdOB, RhAgOB, RhPtOB, RhAuOB, RhCoOB, RhNiOB, RhIrOB, RhTeOB, RhCrOB, RhTaOB and RhAlOB.

FIG. 9 is a graph of extinction coefficient k plotted against index of refraction n for first materials and second materials useful as materials to form alloys for use in an absorber layer or as materials for use to repair a defect in an absorber layer in accordance with some embodiments of the present disclosure. The plotted n and k values are for EUV radiation centered on 13.5 nanometers and are determined using atomic scattering factors under an 0^{th}-order approximation. Another source of these n and k values is a database of such values maintained by The Center for X-Ray Optics (CXRO) withing Lawrence Berkley National Laboratory's Materials Sciences Division. The plot of FIG. 9 includes a “red zone” 902 identified by the border 900. The red zone 902 is defined by a polygon in the plot of FIG. 9 which includes four corners 904, 906, 908, and 910. The four corners correspond to specific coordinates corresponding to index of refraction n and extinction coefficient k coordinates (n, k) in FIG. 9. In the embodiment of FIG. 9, such four coordinates are (0.880, 0.030) 904, (0.880, 0.050) 906, (0.900, 0.050) 908 and (0.900, 0.030) 910. As explained below in more detail, red zone 902 is useful to identify a combination of a first material and a second material that provide an alloy for use in absorber layer 130 that satisfies APSM criteria of an index of refraction between 0.88-0.9, an extinction coefficient of 0.03-0.05 and a thickness of 20-50 nm or a thickness of 15-70 nm. In some embodiments, first material and second material are chosen such that a line connecting the index of refraction and extinction coefficient coordinates for two materials in FIG. 9 passes through at least a portion of the polygon 902 (e.g., through the red zone 902). For example, in FIG. 9 a line between index of refraction and coefficient of extinction coordinates for a first material rhodium (Rh) and second material tellurium (Te) passes through a portion of red zone 902. Similarly, a line between coordinates for rhodium and gold (Au), a line between coordinates for rhodium and platinum (Pt), a line between coordinates for rhodium and tantalum (Ta) and a line between coordinates for rhodium and silver (Ag) pass through a portion of the red zone 902. Selecting a combination of a first material and a second material that meet the foregoing criteria provides an absorber layer for an APSM that exhibits satisfactory phase shift and reflectivity performance while effectively reducing M3D effects before being subjected to a repair process and after being subjected to a repair process. In addition, a combination of a first material and a second material that meet the foregoing criteria provide a material that is useful to repair defects in an APSM utilizing the first material and the second material in its absorber layer. Combinations of a first material and a second material that do not meet the foregoing criteria may not provide an absorber layer that exhibits satisfactory phase shift and reflectivity performance while effectively reducing M3D effects. Combinations of a first material and a second material that do not meet the foregoing criteria may not be useful to repair defects in an APSM absorber layer.

The absorber layer 130 is formed by deposition techniques such as PVD, CVD, ALD, RF magnetron sputtering, DC magnetron sputtering, or IBD. When oxygen, nitrogen or boron is to be included in the alloy of the absorber layer 130, the oxygen, nitrogen or boron can be implanted into an already deposited alloy not including the oxygen, nitrogen, or boron. Alternatively, the target used for a physical vapor deposition process can include materials include oxygen, nitrogen, or boron, e.g., RhN, PdN, RhO, PdO, RhB and PdB.

In embodiments of the present disclosure, by deploying the absorber layer materials as described above, the mask 3D effects caused by EUV phase distortion of an EUV mask, can be reduced. As a result, the size dependent focus shifts and pattern placement errors can be reduced, while desirable aerial image contrast, as evidence by desired normalized image log-slope (NILS), can be achieved.

Referring to FIGS. 2 and 3D, the method 200 proceeds to operation 208, in which a hard mask layer 140 is deposited over the absorber layer 130, in accordance with some embodiments. FIG. 3D is a cross-sectional view of the structure of FIG. 3C after depositing hard mask layer 140 over the absorber layer 130, in accordance with some embodiments.

Referring to FIG. 3D, a hard mask layer 140 is disposed over the absorber layer 130. The hard mask layer 140 possesses different etching characterizes from the absorber layer 130, buffer layer 125 and capping layer 130, and thereby serves as an etch stop layer to allow selective etching of the absorber layer 130, buffer layer 125 and capping layer 120. In the embodiment illustrated in FIG. 3D, hard mask layer 140 is illustrated as a single layer. In other embodiments, the hard mask layer 140 includes two or more sublayers of dissimilar materials. For example, in some embodiments, hard mask layer 140 includes two sublayers, three sublayers or four sublayers of dissimilar materials. In accordance with embodiments of the present disclosure, different combinations of hard mask sublayers and a buffer layer produce improved patterning utilizing dry etching. The several types of materials for a buffer layer have been described above. Materials useful in the sublayers of the hard mask layer 140 include a dielectric materials, such as, CrO, GaN, CrON, CrCON, SiO, SiCO, Y₂O₃, SiCO, SiCON SiN, TaBO, TaBN, TaN, Ta₂O₅, TaO₂, TaO, Ta₂O, MoSi, MoSiN, MoSiO, SiN, SiON, SiO₂, SiCON, SiC and SiCN. As described above, when two or more sublayers are used to form hard mask layer 140, the material used for one sublayer is different from the material used for the other sublayer. For example, in some embodiments of a hard mask layer 140 that includes two sublayers, a first sublayer includes one or more of GaN, CrON, CrCON, SiO, SiCO, Y₂O₃, SiCO or SiCON and the second sublayer includes one or more of TaBO, TaBN, TaN, Ta₂O₅, TaO₂, TaO, Ta₂O, MoSi, MoSiN, MoSiO, SiN, SION, SiO₂, SiCON, SiC or SiCN. In such two sublayer embodiments, the first sublayer has a thickness between 2-20 nm and the second sublayer has a thickness between 2-20 nm. Embodiments in accordance with the present disclosure are not limited to first and second sublayers of the hard mask layer 140 having such thicknesses. For example, the first and second sublayers can have a thickness that is less than 2 nm or greater than 20 nm. If the thickness of the sublayer is too small, the hard mask will not protect the portions of the absorber layer 130, buffer layer 125 or capping layer 120 from the exposure and etching process used to pattern the absorber layer 130, buffer layer 125 and capping layer 120. If the thickness of the sublayers is too large, patterning of the sublayers will become more difficult, resulting in less precise patterning of the hardmask sublayers which can lead to less well defined or inaccurate features being formed in the absorber layer 130, buffer layer 125 and/or capping layer 120.

In some embodiments of a hard mask layer 140 in accordance with disclosed embodiments, the hard mask layer 140 includes three sublayers, a first sublayer includes one or more of GaN, CrON, CrCON, SiO, SiCO, Y₂O₃, SiCO or SiCON; the second sublayer includes one or more of TaBO, Ta₂O₅, TaO₂, TaO, Ta₂O, MoSiO, SiON, SiO₂, or SiCON; and the third sublayer includes one or more of TaBN, TaN, MoSi, MoSiN, SiN, SiC or SiCN In such three sublayer embodiments, the first sublayer has a thickness between 2-20 nm, the second sublayer has a thickness between 2-20 nm and the third sublayer has a thickness between 2-20 nanometers. Embodiments in accordance with the present disclosure are not limited to first, second and third sublayers of the hard mask layer 140 having such thicknesses. For example, the first, second and third sublayers can have a thickness that is less than 2 nm or greater than 20 nm. If the thickness of the sublayer is too small, the hard mask will not protect the portions of the absorber layer 130, buffer layer 125 or capping layer 120 from the exposure and etching process used to pattern the absorber layer 130, buffer layer 125 and capping layer 120. If the thickness of the sublayers is too large, patterning of the sublayers will become more difficult, resulting in less well defined or inaccurate patterning of the hardmask sublayers which will be transferred to the features formed in the absorber layer 130, buffer layer 125 and/or capping layer 120.

In some embodiments of a hard mask layer 140 in accordance with disclosed embodiments, the hard mask layer 140 includes four sublayers, a first sublayer includes one or more of CrON, CrCON, SiO, SiCO, Y₂O₃, SiCO or SiCON; the second sublayer includes one or more of TaBO, Ta₂O₅, TaO₂, TaO, Ta₂O, MoSiO, SiON, SiO₂, or SiCON; the third sublayer includes one or more of TaBN, TaN, MoSi, MoSiN, SiN, SiC or SiCN and the fourth sublayer includes one or more of CrN or Cr₂N. In such four sublayer embodiments, the first sublayer has a thickness between 2-20 nm, the second sublayer has a thickness between 2-20 nm, the third sublayer has a thickness between 2-20 nanometers and the four sublayer has a thickness between 2-20 nm. Embodiments in accordance with the present disclosure are not limited to first, second, third and fourth sublayers of the hard mask layer 140 having such thicknesses. For example, the first, second, third and fourth sublayers can have a thickness that is less than 2 nm or greater than 20 nm. If the thickness of the sublayer is too small, the hard mask will not protect the portions of the absorber layer 130, buffer layer 125 or capping layer 120 from the exposure and etching process used to pattern the absorber layer 130, buffer layer 125 and capping layer 120. If the thickness of the sublayers is too large, patterning of the sublayers will become more difficult, resulting in less well defined or inaccurate patterning of the hardmask sublayers which will be transferred to the features formed in the absorber layer 130, buffer layer 125 and/or capping layer 120.

In some embodiments, the sublayers of hard mask layer 140 are formed using a deposition process such as, for example, CVD, PECVD, or PVD.

In some embodiments, the absorber layer upper surface includes an oxide, e.g., an oxide that is intentionally formed. Such oxide may be formed by oxidizing an upper surface of the absorber layer or the oxide maybe deposited/formed on the upper surface of the absorber layer. In other embodiments, the oxide may be dispersed within the absorber layer, thereby providing at least a portion of the oxygen that is present in some embodiments of the absorber layer materials. In some embodiments a native oxide is formed after the absorber layer has been formed, for example, during the process of etching the absorber layer to pattern it or formed during the process of removing the hard mask layers. Such native oxide may be in the form of a thin layer less than 10 nanometers thick, e.g., 0.5-5 nanometers thick. Such native oxide layer can have a non-uniform thickness. In such instances, to improve the uniformity of the thickness of the oxide layer, an intentionally formed oxide layer is formed as described above. The oxide layer after the formation of the intentional oxide layer has a uniform thickness that can range between 20 to 50 nanometers thick.

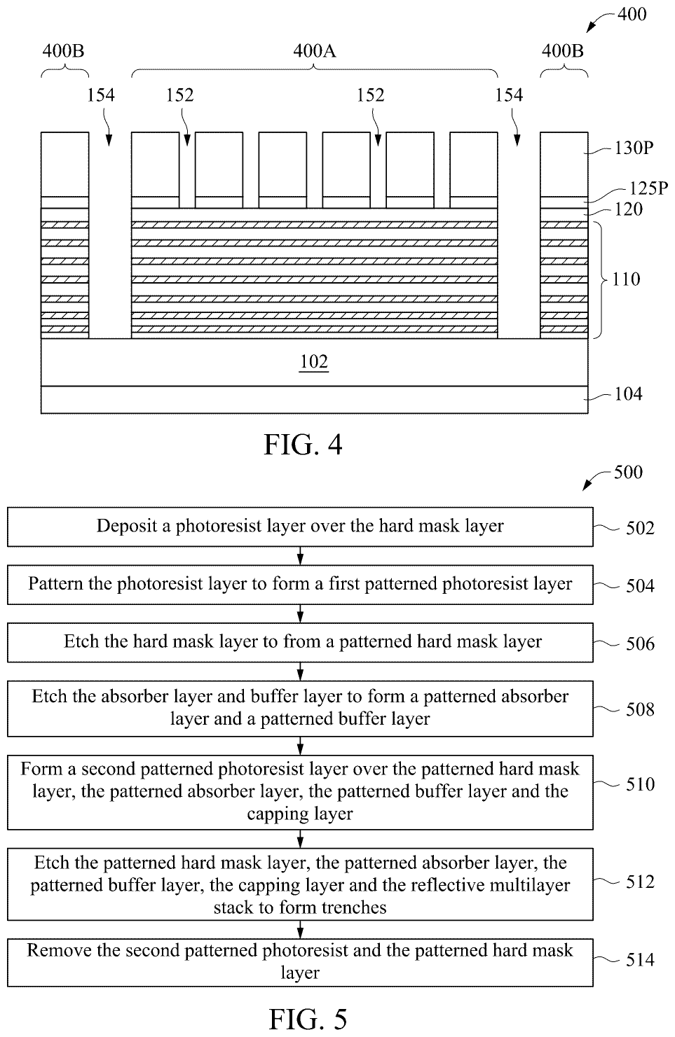

FIG. 4 is a cross-sectional view of an EUV mask 400 that is formed by patterning the absorber layer 130 of the EUV mask blank 100 described above, in accordance with a second aspect of the present disclosure. Referring to FIG. 4, the EUV mask 400 includes a substrate 102, a reflective multilayer stack 110 over a front surface of the substrate 102, a capping layer 120 (not patterned in FIG. 4, but in other embodiments, capping layer 120 is patterned there by exposing an upper surface of the reflective multilayer stack 110) over the reflective multilayer stack 110, a patterned buffer layer 125 over the capping layer 120 and a patterned absorber layer 130P over the capping layer 120. The EUV mask 400 further includes a conductive layer 104 over a back surface of the substrate 102 opposite the front surface.

The patterned absorber layer 130P contain a pattern of openings 152 that correspond to feature patterns to be formed on a semiconductor wafer. The pattern of openings 152 is located in a pattern region 400A of the EUV mask 400, exposing a surface of the capping layer 120. The pattern region 400A is surrounded by a peripheral region 400B of the EUV mask 400. The peripheral region 400B corresponds to a non-patterned region of the EUV mask 400 that is not used in an exposing process during IC fabrication. In some embodiments, the pattern region 400A of EUV mask 400 is located at a central region of the substrate 102, and the peripheral region 400B is located at an edge portion of the substrate 102. The pattern region 400A is separated from the peripheral region 400B by trenches 154. The trenches 154 extend through the patterned absorber layer 130P, buffer layer 125, the capping layer 120, and the reflective multilayer stack 110, exposing the front surfaced of the substrate 102.

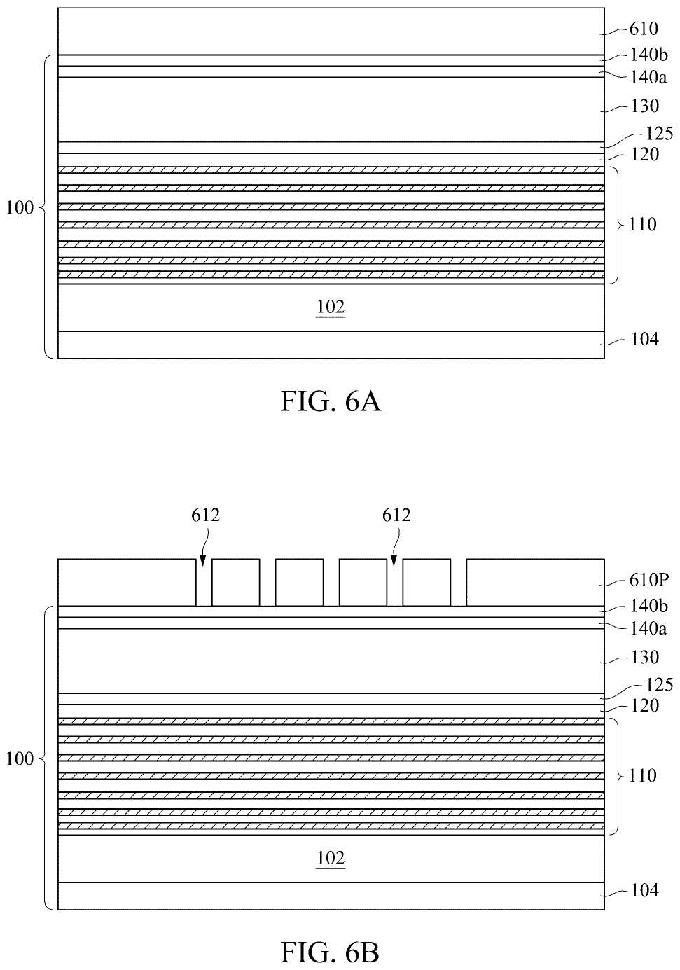

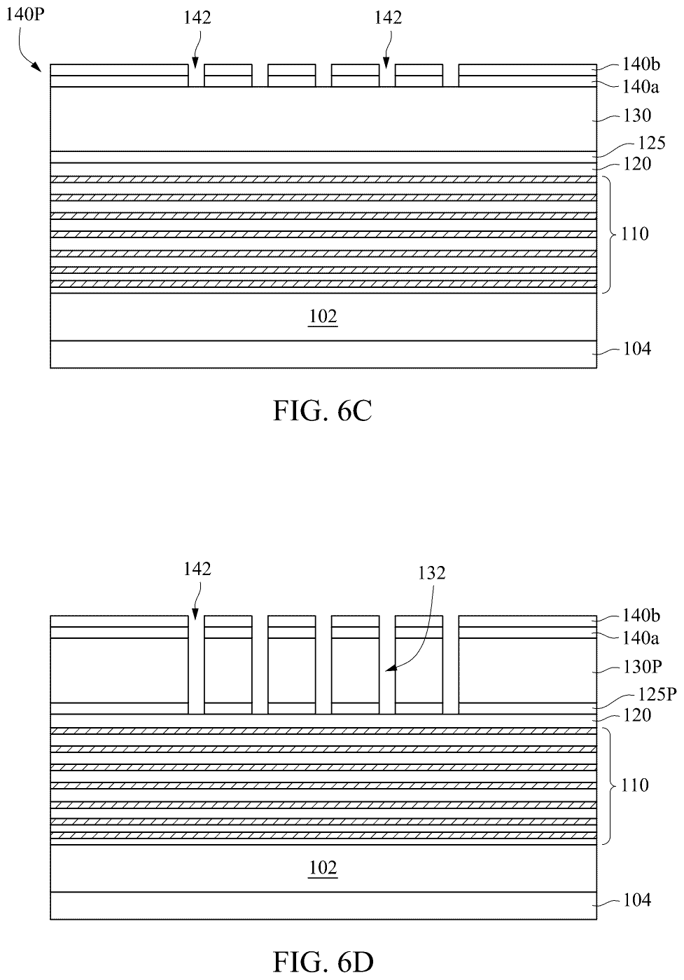

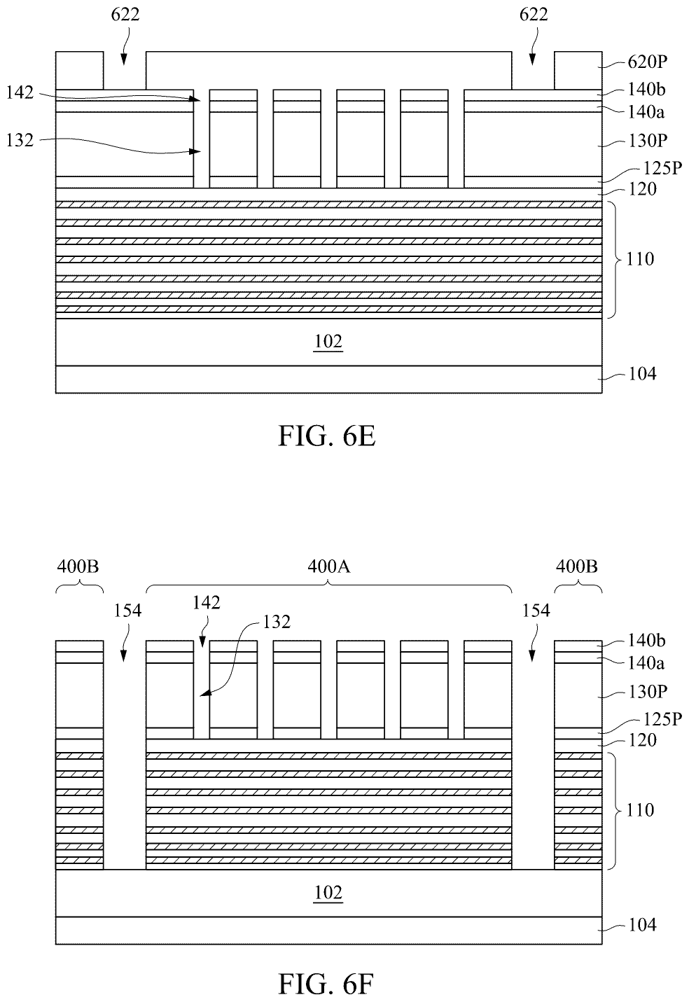

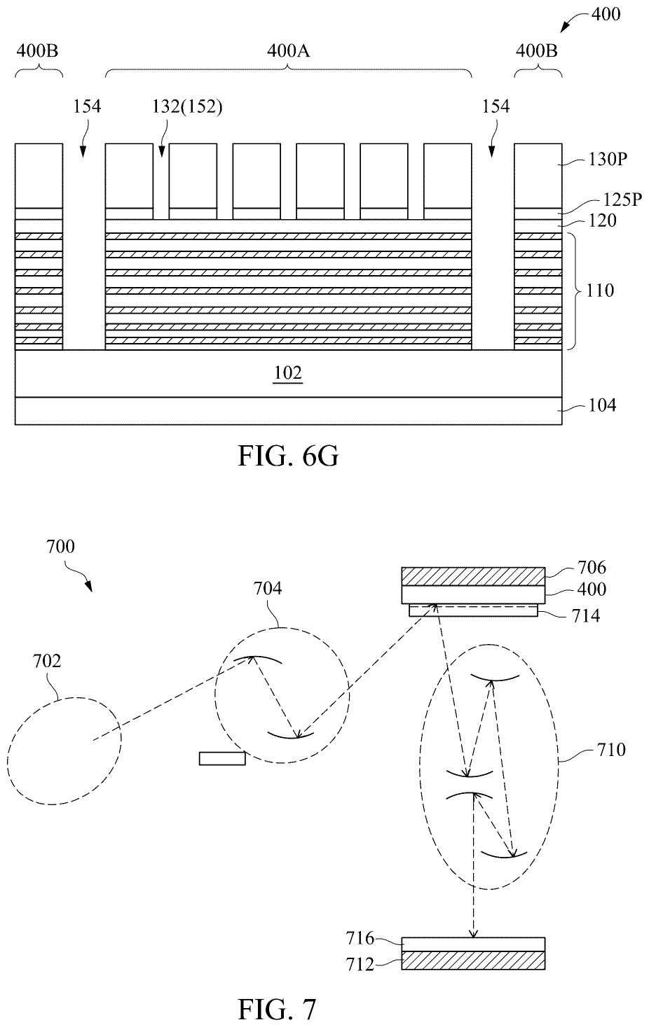

FIG. 5 is a flowchart of a method 500 for fabricating an EUV mask, for example, EUV mask 400, in accordance with some embodiments. FIG. 6A through FIG. 6G are cross-sectional views of the EUV mask 400 at various stages of the fabrication process, in accordance with some embodiments. The method 500 is discussed in detail below, with reference to the EUV mask 400. In some embodiments, additional operations are performed before, during, and/or after the method 500, or some of the operations described are replaced and/or eliminated. In some embodiments, some of the features described below are replaced or eliminated. One of ordinary skill in the art would understand that although some embodiments are discussed with operations performed in a particular order, these operations may be performed in another logical order.

Referring to FIGS. 5 and 6A, the method 500 includes operation 502, in which a photoresist layer 610 is deposited over the hard mask layer formed by a first hard mask sublayer 140a on absorber layer 130 and a second hard mask layer 140b on the first hard mask sublayer 140a, in accordance with some embodiments. FIG. 6A is a cross-sectional view of a structure after depositing the photoresist layer 610 over the hard mask sublayers 140a and 140b, in accordance with some embodiments. The following discussion of formation of a mask proceeds with reference to a hard mask layer that includes two sublayers 140a and 140b. As noted above, hard mask layer can include more than two sublayers of material. When the hard mask layer includes more than two sublayers, the steps described herein for forming and patterning the first and second sublayers 140a and 140b are applicable to the additional sublayers of the hard mask layer 140.

Referring to FIG. 6A, the photoresist layer 610 is disposed over the topmost surface of the EUV mask blank 100, i.e., the upper surface of sublayer 140b of hard mask layer 140. The photoresist layer 610 includes a photosensitive material operable to be patterned by radiation. In some embodiments, the photoresist layer 610 includes a positive-tone photoresist material, and a negative-tone photoresist material or a hybrid-tone photoresist material. In some embodiments, the photoresist layer 610 is applied to the surface of the hard mask layer 140b, for example, by spin coating.

Referring to FIGS. 5 and 6B, the method 500 proceeds to operation 504, in which the photoresist layer 610 is lithographically patterned to form a patterned photoresist layer 610P, in accordance with some embodiments. FIG. 6B is a cross-sectional view of the structure of FIG. 6A after lithographically patterning the photoresist layer 610 to form the patterned photoresist layer 610P, in accordance with some embodiments.

Referring to FIG. 6B, the photoresist layer 610 is patterned by first subjecting the photoresist layer 610 to a pattern of irradiation. Next, the exposed or unexposed portions of the photoresist layer 610 are removed depending on whether a positive-tone or negative-tone resist is used in the photoresist layer 610 with a resist developer, thereby forming the patterned photoresist layer 610P having a pattern of openings 612 formed therein. The openings 612 expose portions of the hard mask sublayer 140b. The openings 612 are located in the pattern region 400A and correspond to locations where the pattern of openings 152 are present in the EUV mask 400 (FIG. 4).

Referring to FIGS. 5 and 6C, the method 500 proceeds to operation 506, in which the sublayers 140b and 140a of hard mask layer 140 are etched using the patterned photoresist layer 610P as an etch mask to form a patterned hard mask layer 140P, in accordance with some embodiments. FIG. 6C is a cross-sectional view of the structure of FIG. 6B after etching the sublayers 140b and 140a of hard mask layer 140 to form the patterned hard mask layer 140P, in accordance with some embodiments.

Referring to FIG. 6C, portions of the sublayers 140b and 140a of hard mask layer 140 that are exposed by the openings 612 are etched to form openings 142 extending through the patterned hard mask layer 140P. The openings 142 expose portions of the underlying absorber layer 130. In some embodiments, the sublayers 140b and 140a of hard mask layer 140 are etched using an anisotropic etch. In some embodiments, the anisotropic etch is a dry etch such as, for example, reactive ion etch (RIE), a wet etch, or a combination thereof. The etch removes the material providing the sublayers 140b and 140a of hard mask layer 140 selectively to the material providing the absorber layer 130. The remaining portions of the hard mask layers 140a and 140b constitute the patterned hard mask layer 140P. If not completely consumed during the etching of the hard mask layer 140, after etching the hard mask layers 140a and 140b, the patterned photoresist layer 610P is removed from the surfaces of the patterned hard mask layer 140P, for example, using wet stripping or plasma ashing.

Referring to FIGS. 5 and 6D, the method 500 proceeds to operation 508, in which the absorber layer 130 is etched using the patterned hard mask layer 140P as an etch mask to form a patterned absorber layer 130P, in accordance with some embodiments. FIG. 6D is a cross-sectional view of the structure of FIG. 6C after etching the absorber layer 130 to form the patterned absorber layer 130P, in accordance with some embodiments.

Referring to FIG. 6D, portions of the absorber layer 130 that are exposed by the openings 142 are etched to form openings 132 extending through the absorber layer 130. In some embodiments, this etching exposes portions of the underlying buffer layer 125. The openings 132 in the patterned absorber layer 130P define the pattern of openings 152 in the EUV mask 400. In some embodiments, the absorber layer 130 is etched using an anisotropic etching process. In some embodiments, the anisotropic etch is a dry etch such as, for example, RIE, a wet etch, or a combination thereof that removes the material providing the absorber layer 130 selective to the material providing the underlying buffer layer 125. For example, in some embodiments, the absorber layer 130 is dry etched with a gas that contains chlorine, such as Cl₂ or BCl₃, or with a gas that contains fluorine, such as NF₃. Argon (Ar) may be used as a carrier gas. In some embodiments, oxygen (O₂) may also be included as the carrier gas. The etch rate and the etch selectivity depend on the etchant gas, etchant flow rate, power, pressure, and substrate temperature. After etching, the remaining portions of the absorber layer 130 constitute the patterned absorber layer 130P. The portions of the buffer layer 125 exposed through the openings 142 are then etched to remove the exposed portions of the buffer layer selective to the underlying capping layer 120 and the remaining portions of the patterned absorber layer 130P. This provides a patterned buffer layer 125P illustrated in FIG. 6D. Though not illustrated in FIG. 6D, in some embodiments in accordance with the present disclosure, portions of capping layer 120 exposed by openings 132 can be etched to expose the upper surface of reflective multilayer stack 110.

Referring to FIGS. 5 and 6E, the method 500 proceeds to operation 510, in which a patterned photoresist layer 620P comprising a pattern of openings 622 is formed over the patterned hard mask layer 140P, patterned buffer layer 125P and the capping layer 120, in accordance with some embodiments. FIG. 6E is a cross-sectional view of the structure of FIG. 6D after forming the patterned photoresist layer 620P comprising openings 622 over the patterned hard mask layer 140P, patterned buffer layer 125P and the capping layer 120, in accordance with some embodiments.

Referring to FIG. 6E, the openings 622 expose portions of the sublayer 140b of the patterned hard mask layer 140P at the periphery of the patterned absorber layer 130P. The openings 622 correspond to the trenches 154 in the peripheral region 400B of the EUV mask 400 (FIG. 4). To form the patterned photoresist layer 620P, a photoresist layer (not shown) is applied over the patterned hard mask layer 140P and the capping layer 120. The photoresist layer fills the openings 142 within the patterned hard mask layer 140P and the openings 132 within the patterned absorber layer 130P and patterned buffer layer 125P. In some embodiments, the photoresist layer includes a positive-tone photoresist material, a negative-tone photoresist material, or a hybrid-tone photoresist material. In some embodiments, the photoresist layer includes a same material as the photoresist layer 610 described above in FIG. 6A. In some embodiments, the photoresist layer includes a different material from the photoresist layer 610. In some embodiments, the photoresist layer is formed, for example, by spin coating. The photoresist layer is subsequently patterned by exposing the photoresist layer to a pattern of radiation, and removing the exposed or unexposed portions of the photoresist layer using a resist developer depending on whether a positive or negative resist is used. The remaining portions of the photoresist layer constitute the patterned photoresist layer 620P.

Referring to FIGS. 5 and 6F, the method 500 proceeds to operation 512, in which the patterned hard mask layer 140P, the patterned absorber layer 130P, the patterned buffer layer 125P, the capping layer 120, and the reflective multilayer stack 110 are etched using the patterned photoresist layer 620P as an etch mask to form trenches 154 in the peripheral region 400B of the substrate 102, in accordance with some embodiments. FIG. 6F is a cross-sectional view of the structure of FIG. 6E after etching the patterned hard mask layer 140P, the patterned absorber layer 130P, the patterned buffer layer 125P, the capping layer 120, and the reflective multilayer stack 110, to form the trenches 154 in the peripheral region 400B of the substrate 102, in accordance with some embodiments.

Referring to FIG. 6F, the trenches 154 extend through the sublayers 140b and 140a of the patterned hard mask layer 140P, the patterned absorber layer 130P the patterned buffer layer 125P, the capping layer 120, and the reflective multilayer stack 110 to expose the surface of the substrate 102. The trenches 154 surround the pattern region 400A of the EUV mask 400, separating the pattern region 400A from the peripheral region 400B.

In some embodiments, the patterned hard mask layer 140P, the patterned absorber layer 130P, the patterned buffer layer 125P, the capping layer 120, and the reflective multilayer stack 110 are etched using a single anisotropic etching process. The anisotropic etch can be a dry etch such as, for example, RIE, a wet etch, or a combination thereof that removes exposed portions of materials of the respective patterned hard mask layer 140P, patterned absorber layer 130P, patterned buffer layer 125P, capping layer 120, and reflective multilayer stack 110, selective to the material providing the substrate 102. In some embodiments, the patterned hard mask layer 140P, the patterned absorber layer 130P, the patterned buffer layer 125P, the capping layer 120, and the reflective multilayer stack 110 are etched using multiple distinct anisotropic etching processes. Each anisotropic etch can be a dry etch such as, for example, RIE, a wet etch, or a combination thereof.

Subsequently, the patterned photoresist layer 620P is removed from the pattern region 400A and the peripheral region 400B of the substrate 102, for example, by wet stripping or plasma ashing. The removal of the patterned photoresist layer 620P from the openings 142 in the patterned hard mask layer 140P and the openings 132 in the patterned absorber layer 130P and patterned buffer layer 125P re-exposes the surfaces of the capping layer 120 in the pattern region 400A.

Referring to FIGS. 5 and 6G, the method 500 proceeds to operation 514, in which the patterned hard mask layer 140P is removed, in accordance with some embodiments. FIG. 6G is a cross-sectional view of the structure of FIG. 6F after removing patterned hard mask layer 140P, in accordance with some embodiments.

Referring to FIG. 6G, the removal of the patterned hard mask layer 140P exposes a surface of patterned absorber layer 130P. In some embodiments, the sublayers 140b and 140a of patterned hard mask layer 140P are removed by an etching process which can be an anisotropic etch or an isotropic etch. In some embodiments, the etch can be a dry etch such as RIE or a wet chemical etch that selectively removes the sublayers of patterned hard mask layer 140P without removing the remaining patterned absorber layer 130P, the patterned buffer layer 125P, the capping layer 120, the reflective multilayer stack 110, and the substrate 102.

After removal of the patterned hard mask layer 140P, the EUV mask 400 may be cleaned to remove any contaminants therefrom. In some embodiments, the EUV mask 400 is cleaned by submerging the EUV mask 400 into an ammonium hydroxide (NH₄OH) solution. In some embodiments, the EUV mask 400 is cleaned by submerging the EUV mask 400 into a diluted hydrofluoric acid (HF) solution.

The EUV mask 400 is subsequently radiated with, for example, an UV light with a wavelength of 193 nm, for inspection of any defects in the patterned region 400A. The foreign matters may be detected from diffusely reflected light. If defects are detected, the EUV mask 400 is further cleaned using suitable cleaning processes.

The patterned absorber layer 130P includes an alloy of a first material and a second material that provides a combination of refractive index, EUV extinction coefficient and thickness properties which allow for forming an absorber layer which reduces mask 3D effects. As a result, a pattern on the EUV mask 400 can be projected precisely onto a semiconductor wafer.

FIG. 7 is a schematic diagram of a lithography system 700, in accordance with some embodiments of the present disclosure. The lithography system 700 may also be referred to herein as a “scanner” that is operable to perform lithography exposing processes with respective radiation sources and exposure modes.

In some embodiments, the lithography system 700 includes a high-brightness light source 702, an illuminator 704, a mask stage 706, a photomask (i.e., EUV mask 400), a projection optics module 710, and a substrate stage 712. In some embodiments, the lithography system may include additional components that are not illustrated in FIG. 7. In further embodiments, one or more of the high-brightness light source 702, the illuminator 704, the mask stage 706, the projection optics module 710, and the substrate stage 712 may be omitted from the lithography system 700 or may be integrated into combined components.

The high-brightness light source 702 may be configured to emit radiation having wavelengths in the range of approximately 1 nanometer (nm) to 250 nm. In some embodiments, the high-brightness light source 702 generates EUV light with a wavelength centered at approximately 13.5 nanometers; accordingly, the high-brightness light source 702 may also be referred to as an “EUV light source.”

In embodiments where the lithography system 700 is an EUV lithography system, the illuminator 704 comprises various reflective optical components, such as a single mirror or a mirror system comprising multiple mirrors. The illuminator 704 may direct light from the high-brightness light source 702 onto the mask stage 706, and more particularly onto the EUV mask 400 that is secured onto the mask stage 706.

The mask stage 706 may be configured to secure the EUV mask 400. In some examples, the mask stage 706 may include an electrostatic chuck (e-chuck) to secure the EUV mask 400.

In some examples, a pellicle 714 may be positioned over the EUV mask 400, e.g., between the EUV mask 400 and the substrate stage 712.

The pellicle 714 may protect the EUV mask 400 from particles and may keep the particles out of focus, so that the particles do not produce an image (which may cause defects on a wafer during the lithography process).

The projection optics module 710 may be configured for imaging the pattern of the EUV mask 400 onto a semiconductor wafer 716 secured on the substrate stage 712. In some embodiments, the projection optics module 710 comprises reflective optics for the EUV lithography system. The light directed from the EUV mask 400, carrying the image of the pattern defined on the EUV mask 400, may be collected by the projection optics module 710. The illuminator 704 and the projection optics module 710 may be collectively referred to as an “optical module” of the lithography system 700.

In some embodiments, the semiconductor wafer 716 may be a bulk semiconductor wafer. For instance, the semiconductor wafer 716 may comprise a silicon wafer. The semiconductor wafer 716 may include silicon or another elementary semiconductor material, such as germanium. In some embodiments, the semiconductor wafer 716 may include a compound semiconductor. The compound semiconductor may include gallium arsenide, silicon carbide, indium arsenide, indium phosphide, another suitable material, or a combination thereof. In some embodiments, the semiconductor wafer 716 includes a silicon-on-insulator (SOI) substrate. The SOI substrate may be fabricated using a separation by implantation of oxygen (SIMOX) process, a wafer bonding process, another applicable process, or a combination thereof. In some embodiments, the semiconductor wafer 716 comprises an undoped substrate. However, in other embodiments, the semiconductor wafer 716 comprises a doped substrate, such as a p-type substrate or an n-type substrate.

In some embodiments, the semiconductor wafer 716 includes various doped regions (not shown) depending on the design requirements of the semiconductor device structure. The doped regions may include, for example, p-type wells and/or n-type wells. In some embodiments, the doped regions are doped with p-type dopants. For example, the doped regions may be doped with boron or boron fluoride. In other examples, the doped regions are doped with n-type dopants. For example, the doped regions may be doped with phosphor or arsenic. In some examples, some of the doped regions are p-doped and other doped regions are n-doped.

In some embodiments, an interconnection structure may be formed over the semiconductor wafer 716. The interconnection structure may include multiple interlayer dielectric layers, including dielectric layers. The interconnection structure may also include multiple conductive features formed in the interlayer dielectric layers. The conductive features may include conductive lines, conductive vias, and/or conductive contacts.

In some embodiments, various device elements are formed in the semiconductor wafer 716. Examples of the various device elements may include transistors (e.g., metal oxide semiconductor field effect transistors (MOSFETs), complementary metal oxide semiconductor (CMOS) transistors, bipolar junction transistors (BJTs), high-voltage transistors, high-frequency transistors, p-channel and/or n-channel field effect transistors (PFETs and/or NFETs), diodes, or other suitable elements. Various processes may be used to form the various device elements, including deposition, etching, implantation, photolithography, annealing, and/or other applicable processes.

The device elements may be interconnected through the interconnection structure over the semiconductor wafer 716 to form integrated circuit devices. The integrated circuit devices may include logic devices, memory devices (e.g., static random access memory (SRAM) devices), radio frequency (RF) devices, input/output (I/O) devices, system-on-chip (SoC) devices, image sensor devices, other applicable devices, or a combination thereof.

In some embodiments, the semiconductor wafer 716 may be coated with a photoresist that is sensitive to EUV light. Various components including those described above may be integrated together and may be operable to perform lithography exposing processes.

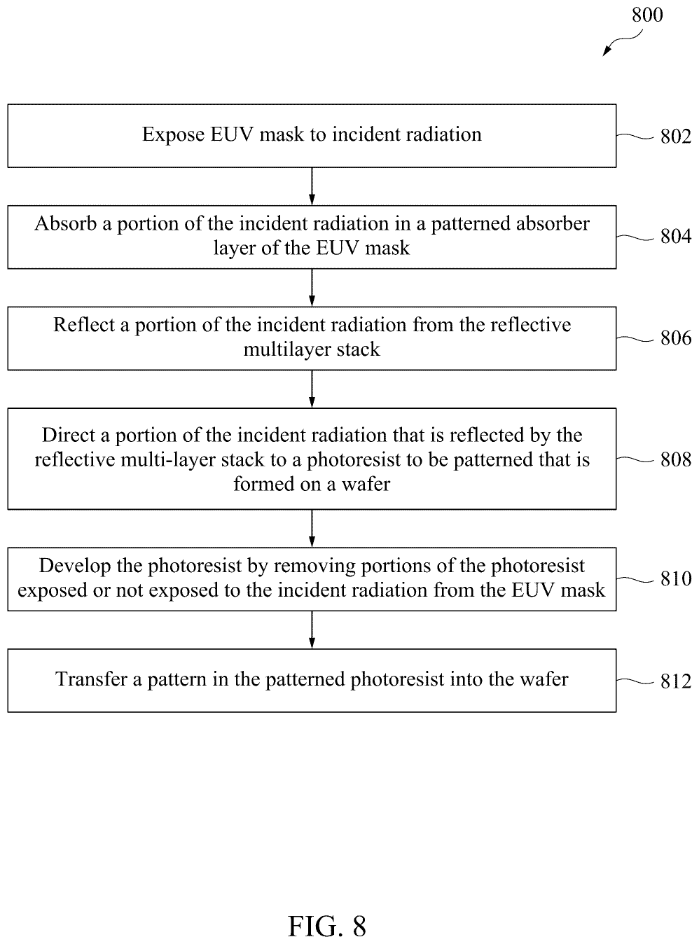

FIG. 8 illustrates a method 800 of using an EUV mask, in accordance with embodiments of the present disclosure. Method 800 includes step 802 of exposing an EUV mask to an incident radiation, e.g., EUV radiation. An example of an EUV mask useful in step 802 includes the EUV mask 400 described above. At step 804, a portion of the incident radiation is absorbed by a patterned absorber layer 130P of the EUV mask 400. At step 806, a portion of the incident radiation is reflected from the reflective multilayer stack 110. A portion of the incident radiation that is reflected by the reflective multilayer stack 110 is directed to a photoresist that is disposed on a semiconductor wafer in step 808. After the photoresist to be patterned has been exposed to the radiation reflected from the EUV mask 400, portions of the photoresist exposed or not exposed to the radiation reflected from the EUV mask 400 are removed at step 810. At step 812, a pattern in the patterned photoresist is transferred into the semiconductor wafer.

One aspect of this description relates to an extreme ultraviolet mask. The EUV mask includes a substrate, a reflective multilayer stack on the substrate, a capping layer on the reflective multilayer stack, a buffer layer on the capping layer and a patterned absorber layer on the buffer layer. The patterned absorber layer has a thickness between 10-50 nanometers and includes an alloy of a first material and a second material, wherein the first material is rhodium (Rh) having an EUV refractive index (n) and an EUV extinction coefficient (k) and wherein the second material is a group 5, group 6, group 9, group 10 or group 11 transition metal having an EUV refractive index (n) greater than the EUV refractive index (n) of rhodium and an EUV extinction coefficient (k) greater than the EUV extinction coefficient (k) of rhodium.

Another aspect of this description relates to relates to a method of forming an EUV mask. The method includes providing an EUV mask blank including a reflective multilayer stack on a substrate. The EUV mask blank further includes a capping layer on the multilayer stack and a buffer layer on the capping layer. In accordance with this aspect of the present disclosure, an absorber layer is on the buffer layer of the mask blank. The absorber layer has a thickness between 20-50 nanometers and the absorber layer includes an alloy of a first material and a second material. The first material is rhodium (Rh) having an EUV refractive index (n) and an EUV extinction coefficient (k). The second material is a group 5, group 6, group 9, group 10, or group 11 transition metal having an EUV refractive index (n) greater than the EUV refractive index (n) of rhodium and an EUV extinction coefficient (k) greater than the EUV extinction coefficient (k) of rhodium. The method includes a step of patterning the absorber layer to form a patterned absorber layer 130P.

Still another aspect of this description relates to an extreme ultraviolet (EUV) mask. The EUV mask includes a substrate, a reflective multilayer stack on the substrate, a capping layer on the reflective multilayer stack, a buffer layer on the capping layer and a patterned absorber layer on the buffer layer. The patterned absorber layer includes an alloy of a first material and a second material, the first material having an EUV refractive index (n) and an EUV extinction coefficient (k) and the second material having an EUV refractive index (n) and an EUV extinction coefficient (k). In accordance with this aspect of the present disclosure, in a plot of EUV refractive index (n) vs EUV extinction coefficient (k) for the first material and the second material, a line between a first material coordinate defined by the EUV refractive index (n) and the EUV extinction coefficient (k) of the first material and a second material coordinate defined by the EUV refractive index (n) and the EUV extinction coefficient (k) of the second material passes through a polygon defined in a plot of four coordinates (n, k), the four coordinates being (0.880, 0.030), (0.880, 0.050), (0.900, 0.050) and (0.900, 0.030).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An extreme ultraviolet (EUV) mask, comprising:
a substrate;
a reflective multilayer stack on the substrate;
a capping layer on the multilayer stack;
a buffer layer on the capping layer; and
a patterned absorber layer having a thickness between 20-50 nanometers on the buffer layer, wherein the patterned absorber layer includes an alloy of a first material and a second material, wherein the first material is rhodium (Rh) having an EUV refractive index (n) and an EUV extinction coefficient (k) and wherein the second material is a group 5, group 6, group 9, group 10 or group 11 transition metal having an EUV refractive index (n) greater than the EUV refractive index (n) of rhodium and an EUV extinction coefficient (k) greater than the EUV extinction coefficient (k) of rhodium.

2. The EUV mask of claim 1, wherein the second material is a period 4,period 5 or period 6 transition metal.

3. The EUV mask of claim 1, wherein the alloy includes one or more of oxygen (O), nitrogen (N) or boron (B).

4. The EUV mask of claim 3, wherein the alloy includes oxygen (O) and one of either nitrogen (N) or boron (B).

5. The EUV mask of claim 1, wherein the alloy provides a phase shift of between 1.17π to 1.2π.

6. The EUV mask of claim 1, wherein the alloy contains 10-75 atomic % rhodium.

7. The EUV mask of claim 3, wherein the alloy contains 2-20 atomic % of oxygen (O), nitrogen (N), boron (B) or combinations thereof.

8. The EUV mask of claim 1, wherein the alloy forms a first sublayer of the patterned absorber layer and the patterned absorber layer further includes a second sublayer, the second sublayer including an alloy of rhodium (Rh).

9. The EUV mask of claim 8, wherein the alloy of rhodium of the second sublayer includes a group 5, group 6, group 9, group 10, or group 11 transition metal.

10. The EUV mask of claim 9, wherein the alloy of rhodium of the second sublayer includes nitrogen (N) or boron (B), but not oxygen (O).

11. The EUV mask of claim 1, wherein the EUV refractive index (n) of rhodium equals about 0.875 and the EUV extinction coefficient (k) of rhodium equals about 0.031.

12. An extreme ultraviolet (EUV) mask, comprising:
a substrate;
a reflective multilayer stack on the substrate;
a capping layer on the multilayer stack; and
a patterned absorber layer over the capping layer, the patterned absorber layer including an alloy of a first material and a second material, the first material having an EUV refractive index (n) and an EUV extinction coefficient (k) and the second material having an EUV refractive index (n) and an EUV extinction coefficient (k), wherein, in a plot of EUV refractive index (n) vs EUV extinction coefficient (k) for the first material and the second material, a line between a first material coordinate defined by the EUV refractive index (n) and the EUV extinction coefficient (k) of the first material and a second material coordinate defined by the EUV refractive index (n) and the EUV extinction coefficient (k) of the second material passes through a polygon defined in a plot of four coordinates (n, k), the four coordinates being (0.880, 0.030), (0.880, 0.050), (0.900, 0.050) and (0.900, 0.030).

13. The extreme ultraviolet mask of claim 12, wherein the first material includes rhodium (Rh) and the second material is a transition metal from group 5, 6, 9, 10, or 11 of the periodic table.

14. The extreme ultraviolet mask of claim 13, wherein the second material includes one or more transition metal selected from tantalum (Ta), chromium (Cr), cobalt (Co), iridium (Ir), nickel (Ni), palladium (Pd), platinum (Pt), silver (Ag) and gold (Au).

15. The extreme ultraviolet mask of claim 12, wherein the first material includes rhodium (Rh) and the second material is aluminum (Al) or tellurium (Te).

16. The extreme ultraviolet mask of claim 12, wherein the alloy includes one or more of oxygen (O), nitrogen (N) or boron (B).

17. The extreme ultraviolet mask of claim 12, wherein the patterned absorber layer includes a first sublayer including the alloy of the first material and the second material, the patterned absorber layer further including a second sublayer, the second sublayer including an alloy of rhodium (Rh).

18. The extreme ultraviolet mask of claim 17, wherein the alloy of rhodium (Rh) of the second sublayer includes a group 5, group 6, group 9, group 10, or group 11 transition metal.

19. A method of forming an EUV mask, comprising:
providing an EUV mask blank including:
a reflective multilayer stack on a substrate,
a capping layer on the multilayer stack,
a buffer layer on the capping layer, and an absorber layer on the buffer layer, wherein the absorber layer has a thickness between 20-50 nanometers and wherein the absorber layer includes an alloy of a first material and a second material, wherein the first material is rhodium (Rh) having an EUV refractive index (n) and an EUV extinction coefficient (k) and wherein the second material is a group 5, group 6, group 9, group 10 or group 11 transition metal having an EUV refractive index (n) greater than the EUV refractive index (n) of rhodium and an EUV extinction coefficient (k) greater than the EUV extinction coefficient (k) of rhodium; and
patterning the absorber layer to form a patterned absorber layer.

20. The method of claim 18, wherein in a plot of EUV refractive index (n) vs EUV extinction coefficient (k) for rhodium and the second material, a line between a first rhodium coordinate defined by the EUV refractive index (n) of rhodium and the EUV extinction coefficient (k) of rhodium and a second material coordinate defined by the EUV refractive index (n) of the second material and the EUV extinction coefficient (k) of the second material passes through a polygon defined in a plot of four coordinates (n, k), the four coordinates being (0.880, 0.030), (0.880, 0.050), (0.900, 0.050) and (0.900, 0.030).
